(19) United States
(12) Patent Application Publication
(10) Pub. No.: US 2014/0333378 A1
(43) Pub. Date: Nov. 13, 2014

(54) Circuit arrangement for generating a radio frequency signal

(71) Applicant: Udo Karthaus, Neu-Ulm (DE)

(72) Inventor: Udo Karthaus, Neu-Ulm (DE)

(21) Appl. No.: 13/889,383

(22) Filed: May 8, 2013

(51) Int. Cl. H03F 3/217; H03F 3/193

(52) U.S. Cl. CPC H03F 3/2171; H03F 3/193
USPC 330/251

(57) ABSTRACT

A circuit arrangement for generating a radio frequency signal is described. The circuit arrangement comprises an RF output port, a shunt capacitor connected to the RF output port, at least two switch-mode amplifiers, each switch-mode amplifier comprising a switch-mode amplifier output port and a series inductive circuit element connected between the switch-mode amplifier output port and the RF output port.

### CROSS REFERENCE TO RELATED APPLICATIONS

This application is related to U.S. Patent Application “Method and circuit for driving a class-D amplifier array”, filed today, May 8, 2013, attorney docking number US002. The entire contents of the foregoing application are incorporated herein by reference.

### SUMMARY OF THE INVENTION

The invention relates to a circuit arrangement for generating a radio frequency (RF) signal and to a power combining circuit.

### BACKGROUND OF THE INVENTION

The use of mobile communications networks has increased over the last decade. Operators of the mobile communications networks have increased the number of base stations in order to meet an increased demand for service by users of the mobile communications networks. The operators of the mobile communications network wish to purchase components for the base stations at a lower price and also wish to reduce the running costs of the base station.

It is therefore a general requirement to design a radio frequency power amplifier such that the radio frequency power amplifier is highly efficient even at backed-off RF output power, or for RF signals with large peak to average power ratio (PAPR, or Crest factor). Traditional class-A, class-AB, class-F amplifiers all have the issue that efficiency decreases at reduced output power, at least proportional to the square root of RF output power. Known architectures overcoming this issue are switch-mode amplifiers such as half-bridge amplifiers. When driven with a periodic continuous wave signal, these circuits ideally produce a square-wave voltage and sinusoidal current waveform, which is called “class-D”. Their output amplitude (envelope) is constant. If signals with varying envelope are needed, there are many options. A first option is to use two half-bridges and a power combiner, and to apply a phase difference to the input signals of each half-bridge. This method is knows as “RF out-phasing” or as “Chireix out-phasing”. A second option is to use delta-sigma modulated bit streams as drive signals. If the digital drive signal has more than 2 levels (more than 1 bit resolution), again more than one half-bridge are needed, and again a power combiner is needed.

It would be desirable to further improve the efficiency of power amplifiers in mobile communications terminals and in other devices comprising power amplifiers.

For this purpose, it would further be desirable to provide for a lossless power combiner circuit that performs mutual load modulation. It would be further desirable to provide for such a combiner circuit that is easy to implement at low cost, low complexity and small size. It would be further desirable to provide for such a combiner circuit that allows for combining a large number of power amplifiers.

It would be further desirable to provide for suitable switch-mode power amplifiers being connected to the power combiner. It would be further desirable to provide for a controller applying suitable modulation schemes to these power amplifiers.

### SUMMARY OF THE INVENTION

These and other objects are solved by a circuit arrangement for generating a radio frequency signal, comprising an RF output port; a shunt capacitor connected to the RF output port; at least two switch-mode amplifiers, each switch-mode amplifier comprising a switch-mode amplifier output port, and a series inductive circuit element connected between the switch-mode amplifier output port and the RF output port.

The present disclosure therefore teaches a combined effect of stepwise activating more and more individual switch-mode amplifiers belonging to a plurality of switch-mode amplifiers with increasing output power and of concurrently modifying the load impedance observed by the individual switch-mode amplifiers. Each additionally activated switch-mode amplifier decreases the apparent load impedance of the already activated switch-mode amplifiers so that in a high output power range each switch-mode amplifier observes a relatively small apparent load impedance. On the other hand, in a low output power range the only activated switch-mode amplifier observes a relatively high apparent load impedance. In this manner, the power level range of power efficient operation of the circuit arrangement can be extended.

In one aspect of the present disclosure, an additional capacitive circuit element is inserted in series with the series inductive circuit element.

In another aspect of the present disclosure, a load is connected to the RF output port, the load having a load impedance, wherein the series inductive circuit elements have series impedances larger than the load impedance of the RF output port.

In yet another aspect of the disclosure, the switch-mode amplifiers are realized on a single or as individual solid state circuits. The semiconductor technology for such solid state circuits can for example be any of CMOS, bipolar, GaAs HBT, SiGe HBT, SiGe BiCMOS, GaAs HEMT, GaAs HEMT, or LDMOS

In yet another aspect of the disclosure, the switch-mode amplifiers are realized by stacked NMOS and PMOS transistors. The number of stacked NMOS and PMOS transistors may be 2, 3 or any other number. A further transistors may be added to tie a node between one transistor of the outer complementary transistor pair and one transistor of the inner complementary transistor pair to a well defined electric potential when said transistors of the outer complementary transistor pair and the inner complementary transistor pair are non-conducting. This further transistor may be of complementary type to said transistors of the outer complementary transistor pair and the inner complementary transistor pair.

The series inductors in one aspect of the disclosure, are realized as bond wires, on-chip spiral inductors, helical inductors, or as transmission lines with their characteristic impedance being larger than a maximal load impedance seen by each switch-mode amplifier.

In yet another aspect of the disclosure, the circuit arrangement comprises a controller configured to determine control signals to the at least two switch.-mode power amplifiers on the basis of delta sigma modulation (class-S), RF out-phasing, polar transmission with the amplitude path being delta sigma modulated, RF pulse width modulation, or based on a combination of any of the above.

Possible applications of the circuit arrangement of this disclosure include wireless communications, wire-line communications, radar and RF sensors.

The present disclosure also teaches an amplifier arrangement comprising an RF output node; a first switch-mode amplifier configured to amplify a first control signal; a second switch-mode amplifier configured to conditionally amplify a second control signal that is temporarily idle during a first operating condition, wherein the second switch-mode amplifier is inactive when the second control signal is idle; and a distributed impedance transforming network connecting an output of the first switch-mode amplifier and an output of the second switch-mode amplifier to the RF output node for combining output signals of the first and second switch-mode amplifiers, wherein a transformed load impedance seen by the first switch-mode amplifier with the second switch-mode amplifier being inactive differs from the transformed load impedance seen by the first switch-mode amplifier with the second switch-mode amplifier being activated.

The distributed impedance transforming network according to one aspect of the invention comprises a first series inductive element connecting an output of the first switch-mode amplifier to the RF output node; a second series inductive element connecting an output of the second switch-mode amplifier to the RF output node; and a shunt capacitive element connected to the RF output node.

In another aspect of the disclosure, the first operating condition is defined by a low output power range of the amplifier arrangement up to a threshold output power, so that the second switch-mode amplifier is inactive when the output power is less than the threshold output power and active when the output power is equal to or greater than the threshold output power.

In another aspect of the disclosure, during a second operating condition the second control signal is in-phase with the first control signal.

In yet another aspect of the disclosure, the first switch-mode amplifier and the second switch-mode amplifier are configured to operate according to an out-phasing amplification scheme.

In yet another aspect of the disclosure, the amplifier arrangement further comprises a control signal generator configured to receive a signal to be amplified and to generate the first control signal and the second control signal, wherein the control signal generator is further configured to determine if the signal to be amplified indicates the first operating condition and to generate the second control signal as an idle signal at least while the first operating condition prevails.

These and other aspects of the invention will be apparent from and elucidated with reference to the embodiment(s) described hereinafter.

### BRIEF DESCRIPTION OF THE FIGURES

FIG. 1 shows a schematic diagram of a three-way load modulating power combiner according to one aspect of the disclosure;

FIG. 2A shows the trend of power efficiency versus output power valid for some aspects of the disclosure;

FIG. 2B illustrates a load impedance observed by one of the amplifiers as a function of output power, which decreases continuously as the other amplifiers are activated with increasing output power;

FIG. 3 shows a schematic diagram of a four-way load modulating power combiner according to another aspect of the disclosure;

FIG. 4 shows a schematic diagram of a CMOS class-D amplifier according to one aspect of the disclosure;

FIG. 5 shows a schematic diagram of a CMOS class-D amplifier according to another aspect of the disclosure;

FIG. 6 shows a schematic diagram of a CMOS class-D amplifier according to yet another aspect of the disclosure;

FIG. 7 shows a schematic block diagram of a level shifter according to one aspect of the disclosure;

FIG. 8 shows a block diagram of circuit configuration according to one aspect of the disclosure including a controller.

### DETAILED DESCRIPTION OF THE INVENTION

The invention will now be described on the basis of the drawings. It will be understood that the embodiments and aspects of the invention described herein are only examples and do not limit the protective scope of the claims in any way. The invention is defined by the claims and their equivalents. It will be understood that features of one aspect or embodiment of the invention can be combined with a feature of a different aspect or aspects and/or embodiments of the invention.

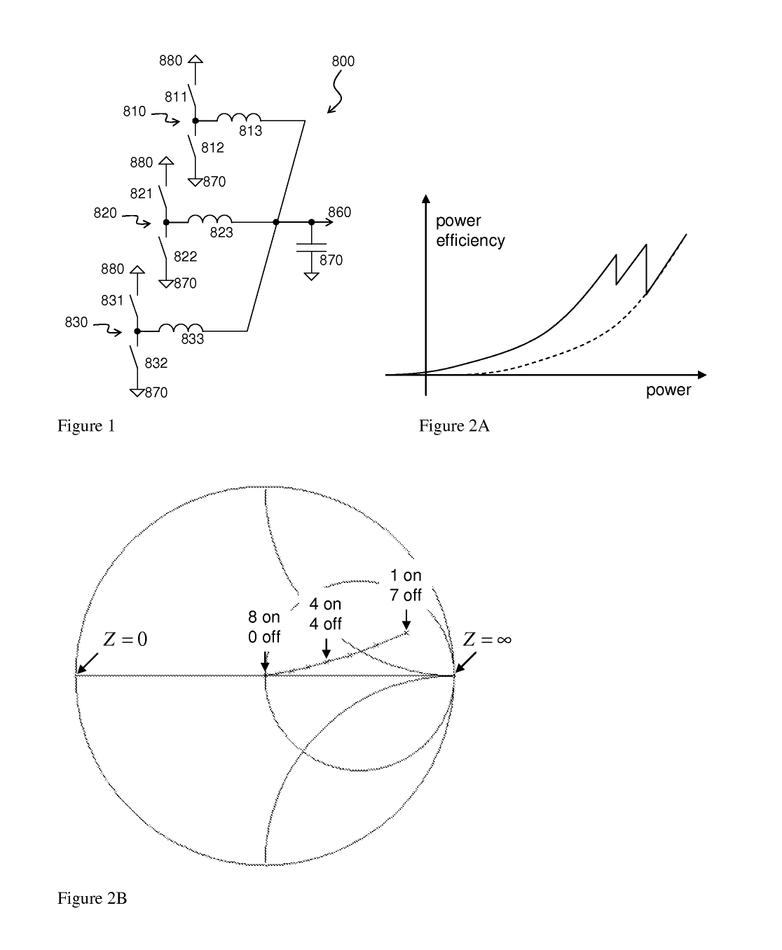

FIG. 1 shows a schematic diagram of a three-way load modulating power combiner 800 according to one aspect of the disclosure. Any other number of inputs greater than or equal to two is also possible. Input power to the combining circuit 800 is provided by class-D amplifiers 810, 820, and 830. The class-D amplifiers can for example be realized with discrete transistors, or on a single integrated circuit or as individual integrated circuits. The class-D amplifiers can be realized in semiconductor technology, for example in CMOS, bipolar, GaAs HBT, SiGe HBT, BiCMOS, GaAs (p)HEMT, GaN (p)HEMT, LDMOS etc. Series inductive circuit elements 813, 823, 833 connect each class-D amplifier's output to a common output port 860. The common output node 860 typically acts as a current summing node, summing the currents through inductors 813, 823, 833. The common output port 860 is connected to at least one shunt capacitive circuit element 870. Series inductive elements can for example be realized as bond wires, on-chip spiral inductors, helical inductors, or high impedance transmission lines. The series inductance circuit elements and the at least one shunt capacitive circuit element 870 can be used to perform impedance transformation from a typically high load impedance connected to the output node 860 to a lower load impedance seen by each of the class-D amplifiers 810, 820 and 830. For high impedance transformation ratios, the absolute value of the impedance of the shunt capacitive circuit element (capacitor) 870 is lower than the load impedance connected to the output 860, and the absolute value of the impedance of each of the series inductors is higher than the load impedance connected to the output 860 multiplied by the number of class-D amplifiers. In this case, the load impedance seen by one class-D amplifier, e.g. 810 is modulated as described below and depicted in FIG. 2B.

FIG. 1 shows half-bridge amplifiers as a non-limiting example of switching amplifiers. When driven with a periodic control signal, voltage is approximately square-wave, and current is approximately sinusoidal. This operating condition is called class-D. Other amplifiers, such as H-bridge (full-bridge) amplifiers, inverse-class-D amplifier, class-D amplifiers with 2 transformer-coupled N-channel switches etc. can also be used as switching amplifiers according to this disclosure.

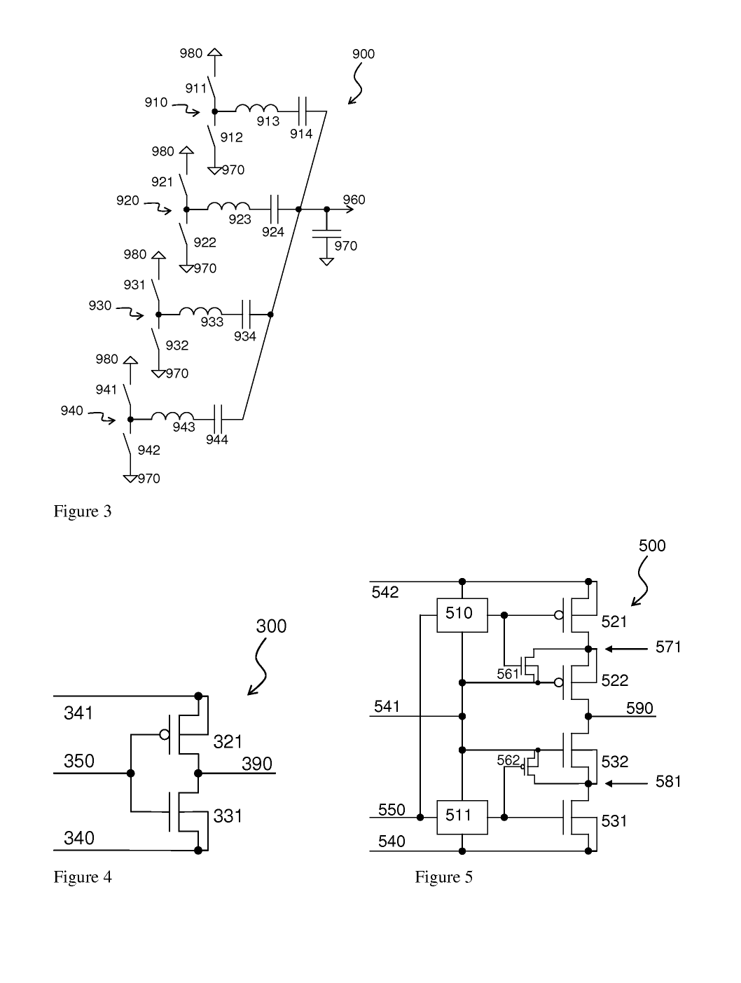

FIG. 2A shows the trend of power efficiency versus output power of a single class-D amplifier (dashed line) and multiple class-D amplifiers according to the configurations of FIG. 1 or 3 (solid line). It is seen that the efficiency is improved in the low power region, where some class-D amplifiers are not active. The discontinuities mark the power levels at which additional amplifiers are activated/de-activated. For comparison, the dashed line indicates efficiency with all amplifiers being active at all power levels.

FIG. 2B illustrates a load impedance observed by one of the amplifiers as a function of output power, which decreases continuously as the other amplifiers are activated with increasing output power; The load impedance is shown in a Smith chart. In this example, a total number of N=8 amplifiers is assumed, but the trend is equal for 3 or any other number of amplifiers. With all amplifiers being active, i.e. at maximum output power, load impedance is “nominal”, i.e. in the center of the Smith chart. This nominal load impedance is in general chosen such that the amplifier can deliver a high output power at reasonably high efficiency. With half of the amplifiers being active (four on, four off), the load impedance seen by any of the four active amplifiers is approximately two times higher, i.e. further to the right on the Smith chart. For the same voltage swing, current—and consequently also power—delivered by each amplifier are 2 times lower. Since only half the amplifiers are active, total output power is 4 times—or 6 dB—lower. Finally, when only 1 out of 8 amplifiers is active, and 7 are idle (off), load impedance seen by this one amplifier is approximately 8 times higher compared to the maximum power case, relatively close to the “Z=∞” point in the Smith chart. For the same voltage swing, current—and consequently also power—delivered by each amplifier are eight times lower. Since only one out of eight amplifiers is active, total output power is 64 times—or 18 dB—reduced. So even at 18 dB back-off from maximum power, the proposed configuration with eight amplifiers and the load modulating combining network can still operate in switch mode, and therefore at high power efficiency. At this backed-off power level, efficiency is further improved by avoiding any switching loss in the seven idle amplifiers.

FIG. 3 shows a schematic diagram of a four-way load modulating power combiner 900 according to another aspect of the disclosure. The number of class-D amplifiers is chosen randomly to be four in this Figure. Any other number of inputs greater than or equal to two is also possible. The configuration is otherwise almost identical to FIG. 1. One difference is the presence of series capacitors 914, 924, 934 and 944 in series to the series inductors 913, 923, 933 and 943. Obviously, the series capacitors 914, 924, 934 and 944 can be placed before or after the series inductors 913, 923, 933 and 943, both options are possible. These capacitors prevent unwanted directional current (DC) flowing through the switches (transistors) 911, 912, 921, 922, 931, 932, 941 and/or 942 and series inductors 913, 923, 933 and/or 943 of two or more class-D amplifiers. Such DC currents would degrade linearity and power efficiency of the amplifier arrangement. These currents can otherwise be very large in case that the average (DC) values of the signals processed by each class-D amplifier are not equal to each other.

FIG. 4 shows a schematic diagram of a CMOS class-D amplifier 300 according to one aspect of the disclosure. In this embodiment, the class-D amplifier is a simple CMOS inverter built of an NMOS transistor 331 and a PMOS transistor 321. The input signal 350 is applied to the gates of both transistors, and the output signal 390 is available at the drains. A negative supply voltage 340, often referred to as “ground” or “vss”, is connected to the NMOS transistor's source, and the positive supply voltage 341, often referred to as “vdd”, is connected to the PMOS transistor's source.

FIG. 5 shows a schematic diagram of a CMOS class-D amplifier 500 according to another aspect of the disclosure. In this embodiment, the low-side switch consists of two stacked NMOS transistors 531 and 532, and the high-side switch consists of two stacked PMOS transistors 521 and 522. By stacking two or more NMOS/PMOS transistors, the CMOS class-D amplifier 500 is able to support a higher supply voltage vdd-vss than the CMOS class-D amplifier 300 depicted in FIG. 4. In this case, gate signals to drive transistors 521 and 531 are in-phase, but at different bias voltage levels. Therefore, dependent on the bias level of the available input signal 550, at least one level shifter 510 or 511 may be needed to shift the signal to the required bias voltage level. For purposes of delay matching between gate signals of transistors 521 and 531, a dummy level shifter may also be used for the other transistor. This is shown the figure, where both transistors, 521 and 531, receive their gate signals through level shifters 510 and 511. Gate voltage of transistors 532 and 522 can be constant at a voltage 541. The inner transistors 532 and 522 are automatically switched at the same time and in the same manner as their corresponding outer transistor 531 and 521, respectively. This is achieved because the outer transistor 531, upon being switched to the conducting state via the input signal 550, pulls node 581 close to the lower supply voltage vss 540, which in turn increase the gate-source voltage v_{GS} of the inner transistor 532 and thus causes the inner transistor 532 to become conducting, too. The inner and outer PMOS transistors 521 and 522 operate in an analog manner. Optionally, to prevent memory effects or even voltage breakdown due to high impedance nodes, transistors 562 and 561 may be added to tie nodes 571 and 581 to a well defined potential when the corresponding transistors connected to those nodes (521 and 522, or 531 and 532) are off.

FIG. 6 shows a schematic diagram of a CMOS class-D amplifier 600 according to yet another aspect of the disclosure. In this embodiment, the low-side switch consists of three stacked NMOS transistors 631, 632 and 633, and the high-side switch consists of three stacked PMOS transistors 621, 622 and 623. In this case, gate signals to drive transistors 621 and 631 are in-phase, but at different bias voltage level. Therefore, dependent on the bias level of the available input signal 650, at least one level shifter 610 or 611 may be needed to shift the signal to the required bias voltage level. For purposes of delay matching between gate signal of transistors 621 and 631, a dummy level shifter may also be used for the other transistor. This is shown the figure, where both transistors, 621 and 631, receive their gate signals through level shifters 610 and 611. In addition, gate signals are needed for transistors 623 and 633. These gate signals need to be opposite phase (or inverted) with respect to gate signals for transistors 621 and 631. Therefore, an inverted input signal 651 is needed. Depending on the bias voltage level of this signal, another level shifter 612 may be needed. Gate voltage of transistors 632 and 622 can be constant at supply voltages 642 and 641, respectively. Optionally, to prevent memory effects or even voltage breakdown due to high impedance nodes, transistors 661, 662, 663 and 644 may be added to tie nodes 671, 672, 681 and 682 to a well defined potential when the corresponding main transistors connected to those nodes (621, 622 and 623, or 631, 632 and 633) are off. Transistors 621 and 631 form an outer complementary transistor pair. Transistors 622 and 632 form a middle complementary transistor pair. Transistors 623 and 633 form an inner complementary transistor pair. Transistors 661 and 662 are further transistors (auxiliary transistors) configured to tie node 671 or 681 between transistor 621 or 631, respectively, of the outer complementary transistor pair and transistor 622 or 632, respectively, of the middle complementary transistor pair to a well defined electric potential 642 or 641, respectively, when said transistors 621, 631 of the outer complementary transistor pair and the middle complementary transistor pair 622, 632 are non-conducting. Transistor 663 is another further transistor (auxiliary transistor) configured to tie a node 672 between one transistor 622, 632 of the middle complementary transistor pair and one transistor 623, 633 of the inner complementary transistor pair to a well defined electric potential when said transistors of the middle complementary transistor pair and the inner complementary transistor pair are non-conducting. Alternatively, as shown in FIG. 6, the nodes 672 and 682 may be tied to an electric potential that is provided by the level shifter 612 and that is based on the inverted input signal 651. The further transistor(s) 661, 662, 663, 664 may be of complementary type to said transistors of the outer complementary transistor pair 621, 631 and the middle complementary transistor pair 622, 632; or to said transistors of the middle complementary transistor pair 622, 632 and the inner complementary transistor pair 632, 633. For example, transistor 661 is a NMOS transistor that is connected to node 671 between the outer transistor 621 and the middle transistor 622, both of which are PMOS.

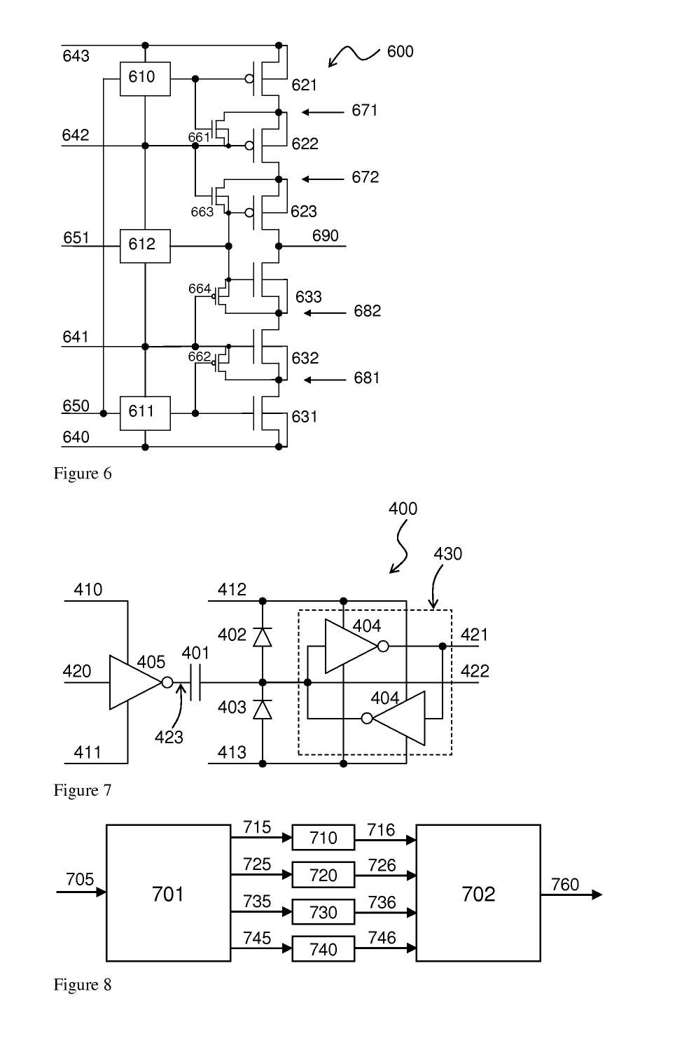

FIG. 7 shows a schematic diagram of a level shifter according to one aspect of the disclosure. This level shifter is an exemplary implementation of level shifters 510, 511, 610, 611 and 612 in FIGS. 5 and 6. Some logic circuitry 405 provides a binary input signal 423. This signal is AC coupled by a capacitor 401. Provided the capacitance of capacitor 401 is sufficiently large, the voltage across this capacitor is almost constant during operation, and the signal is shifted in voltage by the voltage across the capacitor. The output of the capacitor is connected to some logic circuitry 430 with positive feedback. The simplest implementation of such logic circuitry 430 is realized by two cross-coupled inverters 404, but many other implementations are possible, including but not limited to two NAND gates or two NOR gates are any combination of such logic gates. The level shifted output signal is now available at the input node 422 or some internal or output node 421 of the logic circuitry 430. Logic circuitry 430 is supplied with voltages 412 and 413, which correspond to the desired logic high and logic low levels of output signals 412 and 422. The voltage levels of supplies 412 and 422 are the two stable voltages of node 422. Circuitry 430 therefore ensures that the voltage across capacitor 401 remains at the correct value, independent of the duty cycle of the input signal 423. To make the circuit more robust and reliable, protection diodes 402 and 403 may be added to protect the gates of logic circuitry 430 from over-voltage.

FIG. 8 shows a block diagram of circuit configuration 700 according to one aspect of the disclosure including a controller 701. The controller 701 receives an input signal 705, which can be any of a scalar digital signal, a complex (IQ) digital signal, an analog RF signal, a scalar analog baseband signal or a complex (IQ) analog baseband signal. Depending on the instantaneous phase and amplitude (power) of the input signal 705, signals 715, 725, 735 and 745 are generated and fed to switching amplifiers 710, 720, 730, 740. The number of four switching amplifiers is an example only, and any other number of switching amplifiers is possible. Signals 715, 725, 735, 745 may be generated by the controller 701 according to any of the following modulation schemes: delta sigma modulation (class-S), RF out-phasing, polar transmission with the amplitude path being delta sigma modulated, RF pulse width modulation, or a combination of any of the above. Furthermore, the controller 701 may keep one or more of the signals 715, 725, 735, 745 idle under certain conditions of the input signal 705. Such a condition may be that the instantaneous or average power of input signal 705 is below a certain threshold. RF output signals 716, 726, 736, 746 of switching amplifiers 710, 720, 730, 740 are connected to load modulating combiner network or distributed impedance matching network 702. Distributed impedance matching network 702 may be constructed as shown in FIG. 1 and FIG. 3, using series inductive circuit elements 813, 823, 833 or 913, 923, 933, 943 and a shunt capacitive circuit element 870 or 970. The combined RF output signal is available at output node 760.

While various embodiments of the present invention have been described above, it should be understood that they have been presented by way of example, and not limitation. It will be apparent to persons skilled in the relevant arts that various changes in form and detail can be made therein without departing from the scope of the invention. In addition to using hardware (e.g., within or coupled to a central processing unit (“CPU”), micro processor, micro controller, digital signal processor, processor core, system on chip (“SOC”) or any other device), implementations may also be embodied in software (e.g. computer readable code, program code, and/or instructions disposed in any form, such as source, object or machine language) disposed for example in a computer useable (e.g. readable) medium configured to store the software. Such software can enable, for example, the function, fabrication, modelling, simulation, description and/or testing of the apparatus and methods describe herein. For example, this can be accomplished through the use of general program languages (e.g., C, C++), hardware description languages (HDL) including Verilog HDL, VHDL, a layout description language (GDS, GDS II, Gerber, . . . ), a circuit description language (Spice) and so on, or other available programs. Such software can be disposed in any known computer useable medium such as semiconductor, magnetic disc, or optical disc (e.g., CD-ROM, DVD-ROM, etc.). The software can also be disposed as a computer data signal embodied in a computer useable (e.g. readable) transmission medium (e.g., carrier wave or any other medium including digital, optical, analogue-based medium). Embodiments of the present invention may include methods of providing the apparatus described herein by providing software describing the apparatus and subsequently transmitting the software as a computer data signal over a communication network including the internet and intranets.

It is understood that the apparatus and method describe herein may be included in a semiconductor intellectual property core, such as a micro processor core (e.g., embodied in HDL) and transformed to hardware in the production of integrated circuits. Additionally, the apparatus and methods described herein may be embodied as a combination of hardware and software. Thus, the present invention should not be limited by any of the above-described exemplary embodiments, but should be defined only in accordance with the following claims and their equivalents.

1. A circuit arrangement for generating a radio frequency signal, comprising
An RF output port
a shunt capacitor connected to the RF output port
at least two switch-mode amplifiers, each switch-mode amplifier comprising
a switch-mode amplifier output port
a series inductive circuit element connected between the switch-mode amplifier output port and the RF output port.

2. The circuit arrangement of claim 1, with an additional capacitive circuit element in series to the series inductive circuit element.

3. The circuit arrangement of claim 1, further comprising a load connected to the RF output port, the load having a load impedance, wherein the series inductive circuit elements have series impedances larger than the load impedance of the RF output port.

4. The circuit arrangement of claim 1, with the switch-mode amplifiers being realized on a single or as individual solid state circuits.

5. The circuit arrangement of claim 4, with a semiconductor technology of the single solid state circuit or the individual solid state circuits being any of following technologies: CMOS, bipolar, GaAs HBT, SiGe HBT, SiGe BiCMOS, GaAs HEMT, GaAs HEMT, or LDMOS.

6. The circuit arrangement of claim 1, with the switch-mode amplifiers realized by stacked NMOS and PMOS transistors.

7. The circuit arrangement of claim 1, wherein each switch-mode amplifier comprises:
an outer complementary transistor pair configured to receive, as a control signal, an input signal of the circuit arrangement or a signal derived from the input signal; and
an inner complementary transistor pair configured to receive, as a control signal, a constant signal and to replicate a switching behavior of the outer complementary transistor pair.

8. The circuit arrangement of claim 7, further comprising a further transistor configured to tie a node between one transistor of the outer complementary transistor pair and one transistor of the inner complementary transistor pair to a well defined electric potential when said transistors of the outer complementary transistor pair and the inner complementary transistor pair are non-conducting.

9. The circuit arrangement of claim 8, wherein the further transistor is of complementary type to said transistors of the outer complementary transistor pair and the inner complementary transistor pair.

10. The circuit arrangement of claim 1, wherein each switch-mode amplifier comprises:
an outer complementary transistor pair configured to receive, as a control signal, an input signal of the circuit arrangement or a signal derived from the input signal; and
a middle complementary transistor pair configured to receive, as a control signal, a constant signal; and
an inner complementary transistor pair configured to receive, as a control signal, an inverted input signal of the circuit arrangement or an inverted signal derived from the input signal.

11. The circuit arrangement of claim 10, further comprising at least one of
a further transistor configured to tie a node between one transistor of the outer complementary transistor pair and one transistor of the middle complementary transistor pair to a well defined electric potential when said transistors of the outer complementary transistor pair and the middle complementary transistor pair are non-conducting; or
a further transistor configured to tie a node between one transistor of the middle complementary transistor pair and one transistor of the inner complementary transistor pair to a well defined electric potential when said transistors of the middle complementary transistor pair and the inner complementary transistor pair are non-conducting.

12. The circuit arrangement of claim 1, with the series inductors being realized as any of the following options: bond wires, on-chip spiral inductors, helical inductors, transmission lines with their characteristic impedance being larger than a maximal load impedance seen by each switch-mode amplifier.

13. The circuit arrangement of claim 1, further comprising a controller configured to determine control signals to the at least two switch-mode power amplifiers on the basis of any of the following:
delta sigma modulation (class-S),
RF out-phasing,
polar transmission with the amplitude path being delta sigma modulated,
RF pulse width modulation,
a combination of any of the above.

14. The circuit arrangement of claim 1, used for any of the following applications:
wireless communications,
wire-line communications
radar
RF sensors.

15. An amplifier arrangement comprising:
an RF output node;
a first switch-mode amplifier configured to amplify a first control signal;
a second switch-mode amplifier configured to conditionally amplify a second control signal that is temporarily idle during a first operating condition, wherein the second switch-mode amplifier is inactive when the second control signal is idle; and
a distributed impedance transforming network connecting an output of the first switch-mode amplifier and an output of the second switch-mode amplifier to the RF output node for combining output signals of the first and second switch-mode amplifiers, wherein a transformed load impedance seen by the first switch-mode amplifier with the second switch-mode amplifier being inactive differs from the transformed load impedance seen by the first switch-mode amplifier with the second switch-mode amplifier being activated.

16. The amplifier arrangement according to claim 15, wherein the distributed impedance transforming network comprises:
a first series inductive element connecting an output of the first switch-mode amplifier to the RF output node;
a second series inductive element connecting an output of the second switch-mode amplifier to the RF output node; and
a shunt capacitive element connected to the RF output node.

17. The amplifier arrangement according to claim 15, wherein the first operating condition is defined by a low output power range of the amplifier arrangement up to a threshold output power, so that the second switch-mode amplifier is inactive when the output power is less than the threshold output power and active when the output power is equal to or greater than the threshold output power.

18. The amplifier arrangement according to claim 15, wherein during a second operating condition the second control signal is in-phase with the first control signal.

19. The amplifier arrangement according to claim 15, wherein the first switch-mode amplifier and the second switch-mode amplifier are configured to operate according to an out-phasing amplification scheme.

20. The amplifier arrangement according to claim 15, further comprising a control signal generator configured to receive a signal to be amplified and to generate the first control signal and the second control signal, wherein the control signal generator is further configured to determine if the signal to be amplified indicates the first operating condition and to generate the second control signal as an idle signal at least while the first operating condition prevails.
